(19) United States
(12) Patent Application Publication
(10) Pub. No.: US 2013/0308286 A1
(43) Pub. Date: Nov. 21, 2013

(54) METHOD FOR MANUFACTURING ELECTRONIC PART, METHOD FOR TESTING ELECTRONIC PART, SHEET SUBSTRATE, ELECTRONIC PART, AND ELECTRONIC APPARATUS

(71) Applicant: SEIKO EPSON CORPORATION, Tokyo (JP)

(72) Inventor: Kyo HORIE, Okaya (JP)

(73) Assignee: Seiko Epson Corporation, Tokyo (JP)

(21) Appl. No.: 13/890,548

(22) Filed: May 9, 2013

(30) Foreign Application Priority Data
May 16, 2012 (JP) 2012-112201

(51) Int. Cl. H05K 1/11; H05K 3/30; H05K 1/18

(52) U.S. Cl. CPC H05K 1/111; H05K 1/181; H05K 3/301
USPC 361/767; 174/261; 29/832

(57) ABSTRACT

A manufacturing method according to an embodiment of the invention includes a first step of providing a sheet substrate having a piezoelectric resonator element and an integrated circuit disposed on a mounting surface of each substrate region, having implementation electrodes that are electrically connected to the integrated circuit disposed the side facing away from the mounting surface, and disposing wiring lines on the sheet substrate, the wiring liens electrically connecting the piezoelectric resonator element disposed in a first substrate region to the implementation electrode in a second substrate region in the vicinity of the piezoelectric resonator element, a second step of inputting and outputting a signal to and from the piezoelectric resonator element in the first substrate region via the implementation electrodes connected to the wiring lines, and a third step of dividing the sheet substrate along the substrate regions to cut the wiring lines.

### BACKGROUND

1. Technical Field

The present invention relates to a method for manufacturing an electronic part, a method for testing an electronic part, a sheet substrate, an electronic part, and an electronic apparatus, and particularly to a technology that allows a post-implementation test of an electronic device mounted on an electronic part to be readily performed.

2. Related Art

As a method for efficiently manufacturing an electronic part, what is called a multiple-piece manufacturing approach is used in related art. Specifically, a sheet substrate having a plurality of substrate regions is provided, and a piezoelectric oscillator, an IC, and other electronic devices are placed in each of the substrate regions. The sheet substrate is then divided along the boundaries between the substrate regions into individual pieces, which form individual electronic parts.

Further, there is a proposed electronic part in which a piezoelectric resonator element, an integrated circuit, and a plurality of other electronic devices are arranged side by side on a mounting surface of a substrate. The configuration described above allows all the electronic devices to be electrically connected to the rear side of the substrate, for example, via through electrodes that pass through the substrate. The substrate therefore does not need to have a stacked structure for building wiring lines that rearrange the electronic devices. Such a structure is typically required in an electronic part in which electronic devices are implemented on both sides of the substrate. Cost reduction can therefore be achieved because a substrate of a single layer design can be used.

In the electronic part described above, the electronic devices mounted on the electronic part undergo operation check and other verification steps in some cases. For example, when one of the electronic devices is the piezoelectric resonator element described above, a test probe is allowed to come into contact with a connection electrode electrically connected to the piezoelectric resonator element on the substrate, and whether or not the piezoelectric resonator element oscillates or whether the resonant frequency, the CI value, and other parameters of the piezoelectric resonator element fall within appropriate ranges is tested in some cases. The test allows only electronic parts that pass the test to proceed to the following step. As electronic parts are increasingly miniaturized, however, the size of the connection electrode described above is greatly reduced, making it difficult to allow the test probe to come into contact with the connection electrode. In this case, it is conceivable to provide each of the substrate regions with a test electrode electrically connected to an electronic device and having an area larger than the area of the connection electrode and allow the test probe to come into contact with the test electrode. It is, however, also difficult to ensure a sufficient area of the test electrode when the substrate region is miniaturized.

In view of the circumstances described above, JP-A-2003-298000 discloses a sheet substrate 100 having a plurality of substrate regions 102, on each of which an piezoelectric resonator element (not shown) and an integrated circuit 104 electrically connected thereto are mounted, as shown in FIG. 11. The sheet substrate 100 is divided along the boundaries between the substrate regions 102 into individual electronic parts 110. The integrated circuit 104 has a built-in oscillation circuit that excites the piezoelectric resonator element (not shown) to oscillate as an oscillation source and a built-in temperature compensation circuit for compensating an oscillation signal in terms of temperature. Implementation electrodes 106 electrically connected to the integrated circuit 104 are disposed in each of the substrate regions 102.

A wiring line 108 extends from each of the implementation electrodes 106 disposed in the substrate regions 102 adjacent to the substrate region 102 being tested, and the wiring line 108 extends to the substrate region 102 being tested and is electrically connected to the integrated circuit 104. The integrated circuit 104 has a plurality of pad electrodes (not shown), and the wiring line 108 is connected to one of the pad electrodes that is used to write temperature compensation data for the temperature compensation circuit.

In the configuration described in JP-A-2003-298000, after the integrated circuit 104 and the piezoelectric resonator element (not shown) are implemented in each of the substrate regions 102, the piezoelectric resonator element (not shown) in the substrate region 102 being tested is excited and a test probe is allowed to come into contact with the implementation electrodes 106 disposed in the adjacent substrate regions 102 and electrically connected to the integrated circuit 104 in the substrate region 102 being tested. Temperature compensation data corresponding to the piezoelectric resonator element (not shown) being excited are written in the integrated circuit 104 in the substrate region 102 being tested, and then the sheet substrate 100 can be divided along the boundaries between the substrate regions 102 into individual electronic parts 110.

Using the technology described in JP-A-2003-298000 eliminates the necessity to form a test electrode used only in the test step in each of the substrate regions 102 but allows the implementation electrodes 106 in the substrate regions 102 adjacent to the substrate region 102 to be tested to replace the test electrode for the electronic part 110 in the substrate region 102 to be tested.

In JP-A-2003-298000, however, the electronic devices in the substrate region 102 to be tested are electrically connected to the implementation electrodes 106 in the substrate regions 102 adjacent to the substrate region 102 to be tested. Since the wiring lines 108 are left in each electronic part 110 after the individualization of the electronic parts 110, the left wiring lines 108 act as parasitic capacitance (stray capacitance) on the electronic devices and hence can adversely affect the characteristics of the electronic devices.

Further, in each of the electronic parts described above, in which the electronic devices are arranged side by side, some of the electronic devices are disposed in positions shifted to either side of the contour the substrate region. When a post-implementation test is performed on the shifted electronic devices based on the technology described in JP-A-2003-298000, one of the wiring lines 108 left in the electronic part after the individualization is particularly long. In this case, the problem of the parasitic capacitance described above is emphasized.

### SUMMARY

An advantage of some aspects of the invention is to provide not only a method for manufacturing an electronic part in which electronic devices are arranged side by side on a substrate, the electronic part capable of ensuring a sufficient contact area of an electronic-part-side test electrode that is necessary for a test probe and reducing the amount of parasitic capacitance resulting from a test wiring line and acting on the electronic devices, but also a method for testing an electronic part, a sheet substrate, an electronic part, and an electronic apparatus.

The invention can be implemented as the following forms or application examples.

### Application Example 1

This application example is directed to a method for manufacturing an electronic part, the method including a first step of providing a sheet substrate having a plurality of substrate regions arranged in a matrix, having a first electronic device and a second electronic device electrically connected thereto disposed on a mounting surface of each of the plurality of substrate regions, having implementation electrodes that are electrically connected to the second electronic device disposed at angled portions of the surface facing away from the mounting surface of each of the plurality of substrate regions, and having the first electronic device disposed in a position shifted toward one of the angled portions in each of the plurality of substrate regions, and disposing a wiring line on the sheet substrate, the wiring line electrically connecting the first electronic device disposed in the first substrate region to one of the implementation electrodes in the second substrate region, which is adjacent to the first substrate region, specifically, the implementation electrode in the vicinity of the first electronic device, across the boundary between the first substrate region and the second substrate region, a second step of disposing the first electronic device in each of the plurality of substrate regions and inputting and outputting a signal to and from the first electronic device via the implementation electrode connected to the wiring line, and a third step of dividing the sheet substrate along the boundary to cut the wiring line.

Since the method described above allows the first electronic device in the first substrate region to be connected to the implementation electrode disposed in the second substrate region and closest to the first electronic device, the wiring line, which connects the first electronic device to the implementation electrode, can be short, whereby the wiring line left in each of the first and second substrate regions after the sheet substrate is divided can be short. The method for manufacturing an electronic part therefore ensures a sufficient contact area of an electronic-part-side test electrode that is necessary for a test probe and reduces the amount of parasitic capacitance acting on the electronic device.

### Application Example 2

This application example of the invention is directed to the method for manufacturing an electronic part according to Application Example 1, wherein after the second step, the second electronic device is disposed in each of the substrate regions.

Since the method described above allows the second electronic device to be implemented only in a substrate region where the implemented first electronic device operates in a satisfactory manner, no second electronic device is wasted and cost reduction is achieved.

### Application Example 3

This application example of the invention is directed to a method for testing an electronic part, the method including providing a sheet substrate having a plurality of substrate regions arranged in a matrix, having a first electronic device and a second electronic device electrically connected thereto disposed on a mounting surface of each of the plurality of substrate regions, having implementation electrodes that are electrically connected to the second electronic device disposed at angled portions of the surface facing away from the mounting surface of each of the plurality of substrate regions, and having the first electronic device disposed in a position shifted toward one of the angled portions in each of the plurality of substrate regions, disposing a wiring line on the sheet substrate, the wiring line electrically connecting the first electronic device disposed in the first substrate region to one of the implementation electrodes in the second substrate region, which is adjacent to the first substrate region, specifically, the implementation electrode in the vicinity of the first electronic device, disposing the first electronic device in each of the plurality of substrate regions, and inputting and outputting a signal to and from the first electronic device via the implementation electrode connected to the wiring line.

From the same reason described in Application Example 1, the method for testing an electronic part ensures a sufficient contact area of an electronic-part-side test electrode that is necessary for a test probe and reduces the amount of parasitic capacitance acting on the electronic devices.

### Application Example 4

This application example of the invention is directed to a sheet substrate having a plurality of substrate regions arranged in a matrix, having a first electronic device and a second electronic device electrically connected thereto disposed on a mounting surface of each of the plurality of substrate regions, having implementation electrodes that are electrically connected to the second electronic device disposed at angled portions of the surface facing away from the mounting surface of each of the plurality of substrate regions, having the first electronic device disposed in a position shifted toward one of the angled portions in each of the plurality of substrate regions, and a wiring line that electrically connects the first electronic device disposed in the first substrate region to one of the implementation electrodes in the second substrate region, which is adjacent to the first substrate region, specifically, the implementation electrode in the vicinity of the first electronic device, across the boundary between the first substrate region and the second substrate region.

From the same reason described in Application Example 1, the sheet substrate ensures a sufficient contact area of an electronic-part-side test electrode that is necessary for a test probe and reduces the amount of parasitic capacitance acting on the electronic devices.

### Application Example 5

This application example of the invention is directed to the sheet substrate according to Application Example 4, wherein in the substrate regions, in the substrate region which is disposed next to the circumferential edge of the sheet substrate and in which the side toward which the first electronic device is shifted is located next to the circumferential edge of the sheet substrate, a substrate piece is provided in the vicinity of the substrate region, and a test electrode connected to the wiring line is provided on the rear side of the substrate piece.

The configuration described above allows the first electronic devices in all the substrate regions to be tested in the same manner described in Application Example 1.

### Application Example 6

This application example of the invention is directed to an electronic part including the first electronic device and the second electronic device disposed in each of the plurality of substrate regions of the sheet substrate according to Application Example 4 or 5, wherein the sheet substrate is divided along the boundaries between the substrate regions into individual pieces.

From the same reason described in Application Example 1, the electronic part ensures a sufficient contact area of an electronic-part-side test electrode that is necessary for a test probe and reduces the amount of parasitic capacitance acting on the electronic devices.

### Application Example 7

This application example of the invention is directed to the electronic part according to Application Example 6, wherein the first electronic device is an resonator element, and the second electronic device is an integrated circuit.

The configuration described above can form a piezoelectric device that oscillates by itself, and from the same reason described in Application Example 2, no integrated circuit is wasted and cost reduction is achieved.

### Application Example 8

This application example of the invention is directed to an electronic apparatus in which the electronic part according to Application Example 6 or 7 is disposed.

From the same reason described in Application Example 1, the electronic apparatus ensures a sufficient contact area of an electronic-part-side test electrode that is necessary for a test probe and reduces the amount of parasitic capacitance acting on the electronic devices.

### BRIEF DESCRIPTION OF THE DRAWINGS

The invention will be described with reference to the accompanying drawings, wherein like numbers reference like elements.

FIG. 1 shows a plan view of electronic parts (before individualization) according to an embodiment.

FIG. 2 is an enlarged view of a portion surrounded by the dashed line in FIG. 1.

FIG. 3 is a bottom view of the electronic parts (before individualization) according to the embodiment.

FIG. 4 is an enlarged view of a portion surrounded by the dashed line in FIG. 3.

FIG. 5 is a plan view of the electronic part (after individualization) according to the embodiment.

FIG. 6 is a cross-sectional view of the electronic part taken along the line A-A in FIG. 5.

FIGS. 7A to 7C are cross-sectional views taken along the line A-A in FIG. 1 and showing steps of manufacturing the electronic part according to the embodiment, FIG. 7A showing a test step after a piezoelectric resonator element is implemented, FIG. 7B showing an implementation step of implementing in integrated circuit and a cap, and FIG. 7C showing an electronic part individualization step.

FIGS. 8A to 8C are cross-sectional views taken along the line B-B in FIG. 1 and showing the steps of manufacturing the electronic part according to the embodiment, FIG. 8A showing the test step after a piezoelectric resonator element is implemented, FIG. 8B showing the implementation step of implementing in integrated circuit and a cap, and FIG. 8C showing the electronic part individualization step.

FIG. 9 is a partial bottom view of electronic parts (before individualization) according to a variation.

FIG. 10 is a schematic view showing an electronic apparatus that accommodates the electronic part according to the embodiment.

FIG. 11 is a bottom view of electronic parts described in JP-A-2003-298000.

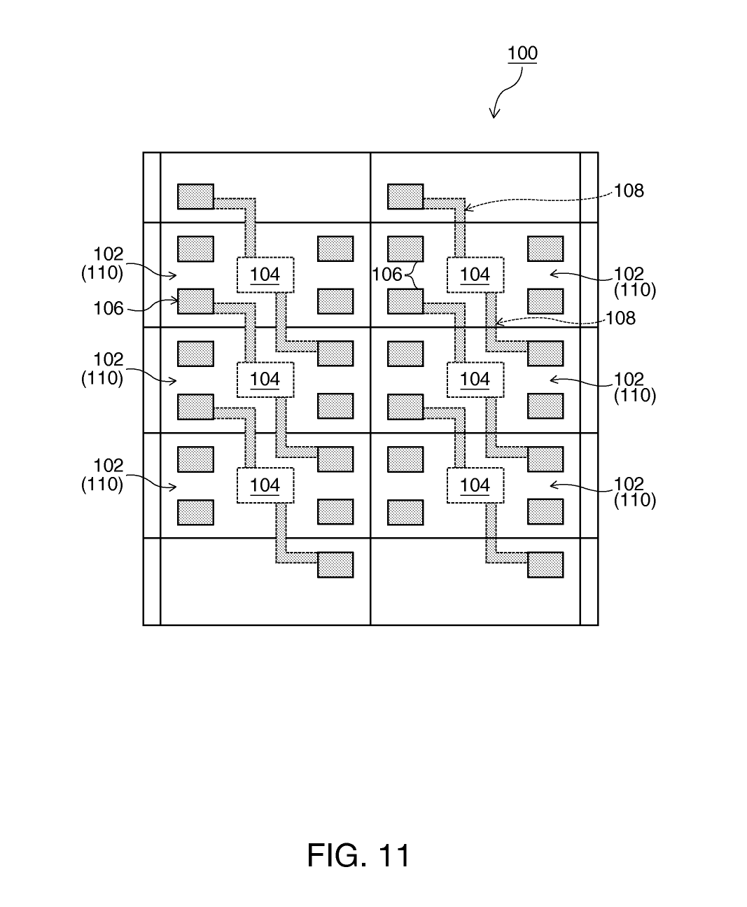

### DESCRIPTION OF EXEMPLARY EMBODIMENTS

The invention will be described below in detail with reference to an embodiment shown in the drawings. It is, however, noted that components described in the embodiment and the types, combinations, shapes, relative arrangements, and other characteristics of the components are not intended to limit the scope of the invention only thereto but are presented only by way of example of description unless otherwise stated.

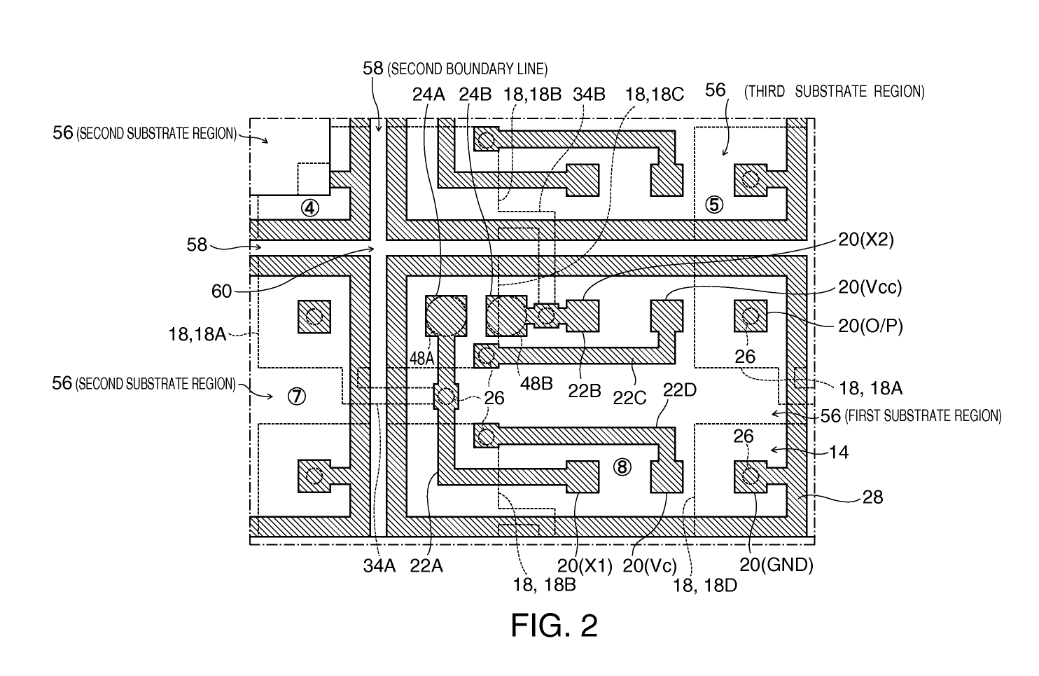

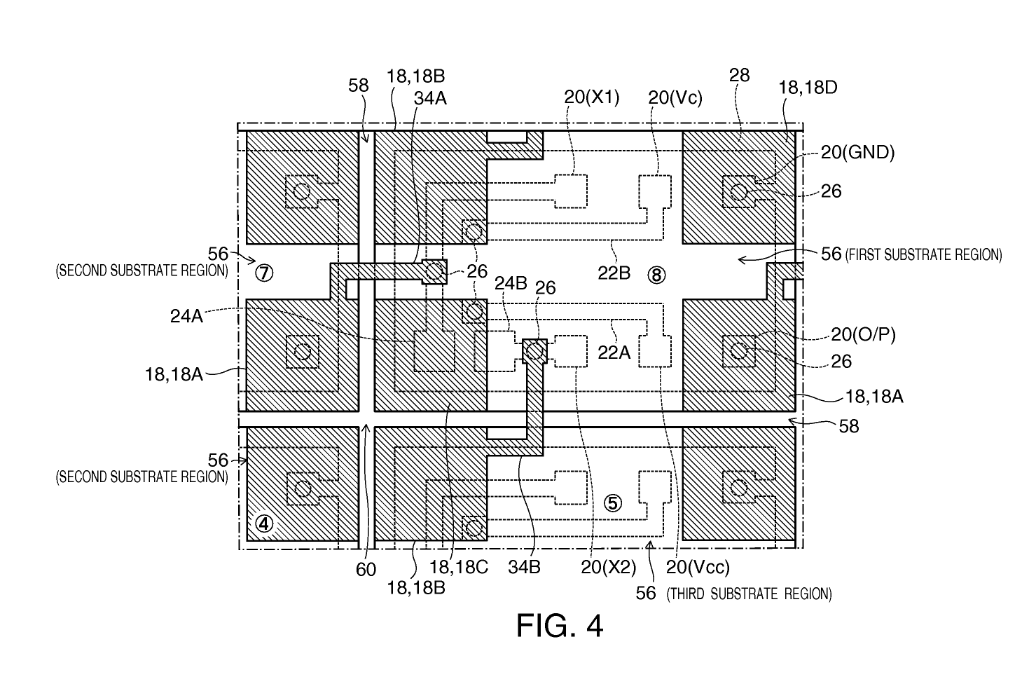

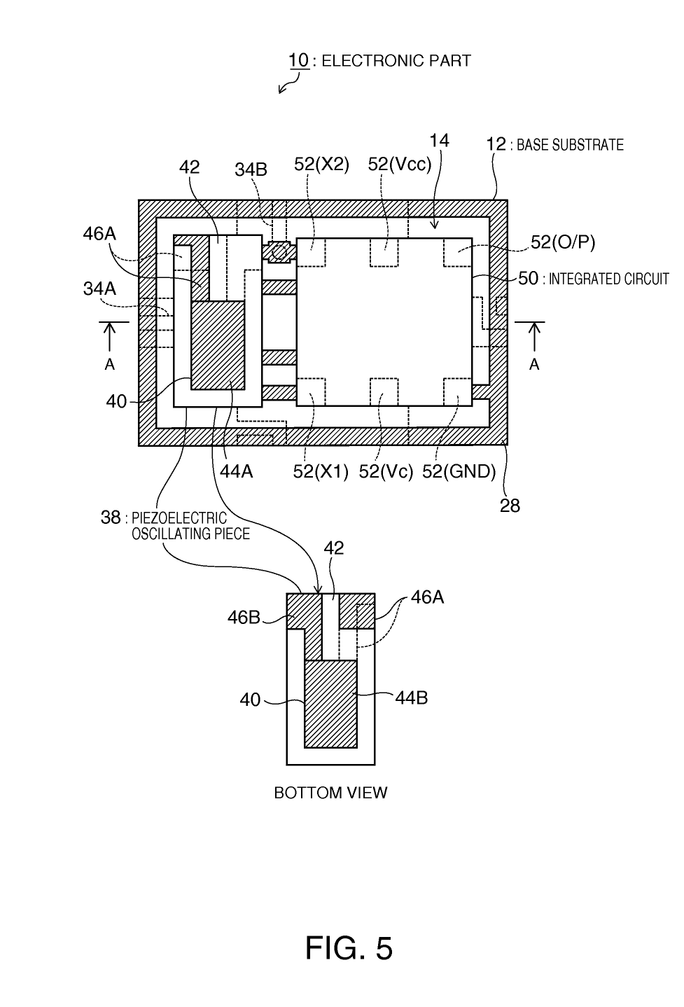

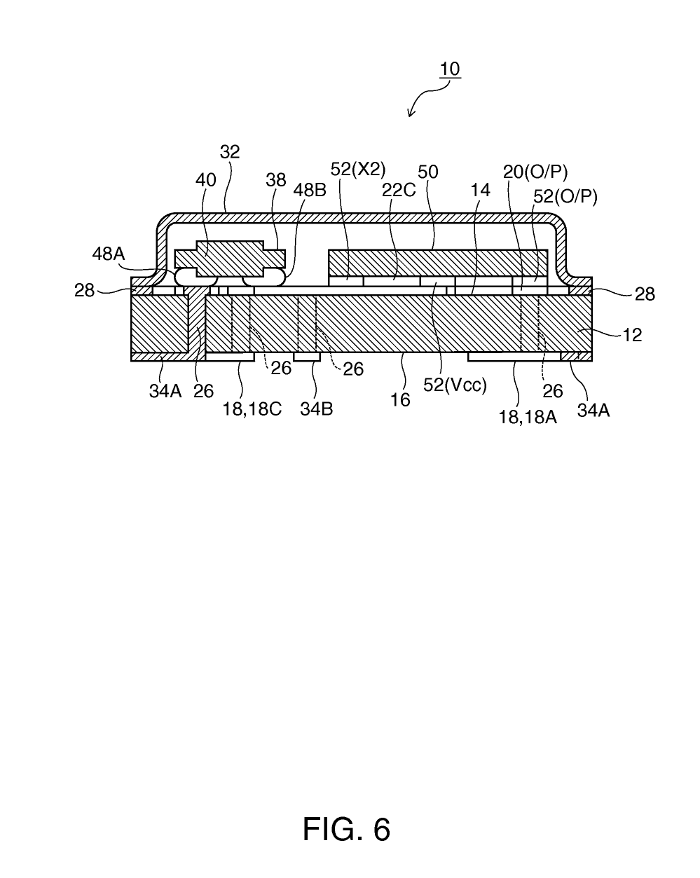

FIG. 5 is a plan view showing an electronic part (after individualization) according to the present embodiment, and FIG. 6 is a cross-sectional view of the electronic part taken along the line A-A in FIG. 5. It is noted that a cap is omitted in FIG. 5. Further, FIG. 2 corresponds to a state in which a piezoelectric resonator element 38 and an integrated circuit 50 are removed from the state in FIG. 5, and FIG. 4 is a bottom view of an electronic part 10 according to the present embodiment.

The electronic part 10 according to the present embodiment has a form in which the piezoelectric resonator element 38 and the integrated circuit 50 are arranged side by side on a base substrate 12 and a cap 32 that accommodates the piezoelectric resonator element 38 and the integrated circuit 50 is bonded to the base substrate 12. The electronic part 10 is therefore a piezoelectric device that oscillates by itself when it externally receives electric power.

The piezoelectric resonator element 38 is made of quartz or any other piezoelectric material. In the present embodiment, the piezoelectric resonator element 38 is, for example, a thickness-shear resonator element using a quartz AT-cut substrate. The piezoelectric resonator element 38 includes an oscillating portion 40, which oscillates in a thickness-shear mode, and a mount portion 42, which is bonded to a second central substrate 22. An excitation electrode 44A (X1) is disposed on the upper surface of the oscillating portion 40, and an excitation electrode 44B (X2) is disposed on the lower surface of the oscillating portion 40. A drawn electrode 46A is drawn from the excitation electrode 44A, and a drawn electrode 46B is drawn from the excitation electrode 44B. The drawn electrode 46B is drawn to the lower surface of the mount portion 42. The drawn electrode 46A is drawn to the lower surface of the mount portion 42 via the upper surface and a side surface of the mount portion 42. The piezoelectric resonator element 38 can alternatively be a tuning-fork resonator element, a double-ended tuning-fork resonator element, a SAW resonance piece, or a gyro resonator element. In the present embodiment, the piezoelectric resonator element 38 is disposed in a position shifted toward an angled portion of the circumferential edge of the base substrate 12, and the drawn electrodes 46A and 46B are disposed in positions shifted toward the angled portion (disposed in positions where the drawn electrodes 46A and 46B overlap with an implementation electrode 18C (Vcc), which will be described later, in a plan view).

The integrated circuit 50 is formed of an oscillation circuit that drives the piezoelectric resonator element 38 as an oscillation source, a temperature compensation circuit that compensates an oscillation signal from the oscillation circuit in terms of temperature, and other circuits integrated with each other. Pad electrodes 52 are disposed on an active surface (lower surface) of the integrated circuit 50. The pad electrodes 52 include connection terminals (X1, X2) electrically connected to the piezoelectric resonator element 38, a power supply terminal (Vcc) that externally receives electric power, a ground terminal (GND), an output terminal through which the oscillation signal is outputted (O/P), and an adjustment terminal (Vc) used, for example, for frequency adjustment.

The base substrate 12 is made of a ceramic material or any other suitable insulating material and has a mounting surface 14 on which the piezoelectric resonator element 38 and the integrated circuit 50 are mounted and an implementation surface 16 that faces away from the mounting surface 14.

Mount electrodes 24A and 24B are disposed on the mounting surface 14 of the base substrate 12 in the positions facing the drawn electrodes 46A and 46B, as shown in FIG. 2. Further, connection electrodes 20 (X1, X2, O/P, Vc, Vcc, and GND) are disposed on the mounting surface 14 in the positions facing the pad electrodes 52. On the other hand, implementation electrodes 18 (18A (O/P), 18B (Vc), 18C (Vcc), and 18D (GND)) are disposed at angled portions of the circumferential edge of the lower surface of the implementation surface 16 of the base substrate 12, as shown in FIG. 4.

The mount electrode 24A and the connection electrode 20 (X1) are electrically connected to each other via a routing electrode 22A, and the mount electrode 24B and the connection electrode 20 (X2) are also electrically connected to each other via a routing electrode 22B.

The connection electrode 20 (O/P) and the implementation electrode 18A are electrically connected to each other via a through electrode 26, which passes through the base substrate 12, and the connection electrode 20 (GND) and the implementation electrode 18D are also electrically connected to each other via another through electrode 26.

A routing electrode 22C extends from the connection electrode 20 (Vcc) to a position immediately above the implementation electrode 18C, and the routing electrode 22C and the implementation electrode 18C are electrically connected to each other via a through electrode 26. The connection electrode 20 (Vcc) is therefore electrically connected to the implementation electrode 18C.

A routing electrode 22D extends from the connection electrode 20 (Vc) to a position immediately above the implementation electrode 18B, and the routing electrode 22D and the implementation electrode 18B are electrically connected to each other via a through electrode 26. The connection electrode 20 (Vc) is therefore electrically connected to the implementation electrode 18B.

The piezoelectric resonator element 38 is boned onto the base substrate 12 in a form in which the drawn electrode 46A and the mount electrode 24A are bonded to each other with a conductive adhesive 48A and the drawn electrode 46B and the mount electrode 24B are bonded to each other with a conductive adhesive 48B. As a result, the piezoelectric resonator element 38 is supported in the form of a cantilever by the base substrate 12 with the mount portion 42 acting as a fixed end and electrically connected to the mount electrodes 24A and 24B.

Further, the integrated circuit 50 is electrically connected to the connection electrodes 20, the mount electrodes 24, and the implementation electrodes 18 by bonding the pad electrodes 52 (X1, X2, O/P, Vc, Vcc, and GND) on the integrated circuit 50 to the connection electrodes 20 (X1, X2, O/P, Vc, Vcc, and GND). The integrated circuit 50 is therefore driven when it receives electric power through the implementation electrode 18C (Vcc) with the implementation electrode 18D (GND) grounded. When the integrated circuit 50 applies an AC voltage to the piezoelectric resonator element 38 via the pad electrodes 52 (X1, X2), the piezoelectric resonator element 38 oscillates at a predetermined resonant frequency, and the integrated circuit 50 can output an oscillation signal associated with the oscillation through the implementation electrode 18A (O/P). Further, operation of writing data to the integrated circuit 50 and other operation can be performed via the implementation electrode 18B (Vc).

A frame-shaped metalized portion 28 is so positioned on the mounting surface 14 of the base substrate 12 that the metalized portion 28 surrounds the piezoelectric resonator element 38 and the integrated circuit 50. The metalized portion 28 is connected to the connection electrode 20 (GND). The cap 32, which is made of a metal, is bonded to the base substrate 12 via the metalized portion 28, which works as a bonding surface. The cap 32 therefore not only hermetically seals the piezoelectric resonator element 38 and the integrated circuit 50 but also works as an electrostatic shield against the environment.

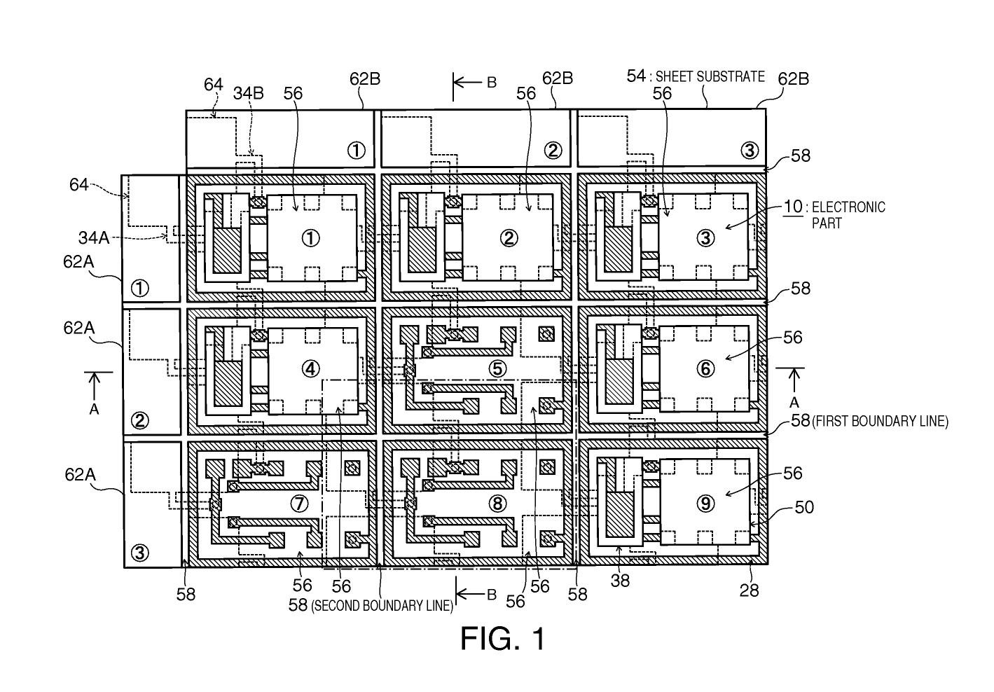

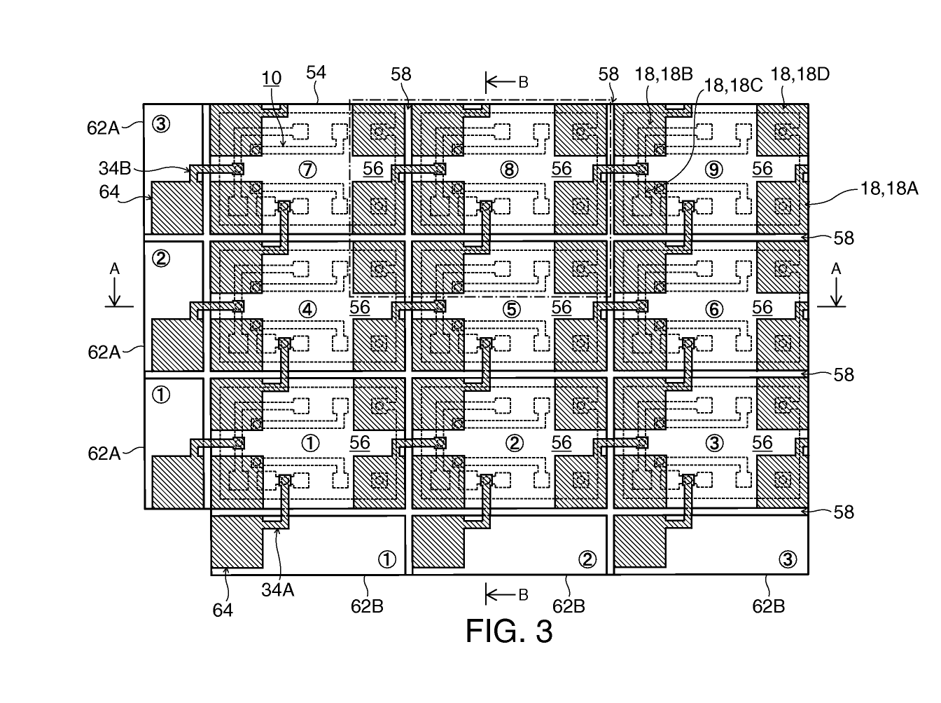

FIG. 1 is a plan view showing electronic parts (before individualization) according to the present embodiment. FIG. 2 is an enlarged view showing the portion surrounded by the dashed line in FIG. 1. FIG. 3 is a bottom view of the electronic parts (before individualization) according to the present embodiment. FIG. 4 is an enlarged view showing the portion surrounded by the dashed line in FIG. 3. In FIG. 1, no cap 32 is shown, and the piezoelectric resonator element 38 and the integrated circuit 50 are omitted in part of FIG. 1.

The electronic parts 10 according to the present embodiment are produced by providing a sheet substrate 54 having a plurality of substrate regions 56, each of which forms the base substrate 12, implementing the piezoelectric resonator element 38, the integrated circuit 50, and the cap 32 in each of the substrate regions 56, and then dividing the sheet substrate 54 along the boundaries between the substrate regions 56 into individual parts.

In the present embodiment, an input/output test is performed on the piezoelectric resonator element 38 after the piezoelectric resonator element 38 is implemented. Now, a first substrate region be the substrate region 56 in which the piezoelectric resonator element 38 to be tested is implemented and second substrate regions be the substrate regions 56 present around the first substrate region.

Although will be described later in detail, the present embodiment is characterized in that an input/output test on the piezoelectric resonator element 38 is performed after wiring lines 34A and 34B that electrically connect the piezoelectric resonator element 38 to be tested to the implementation electrodes 18 that are not only present in second substrate region and third substrate region adjacent to the first substrate region, in which the piezoelectric resonator element 38 to be tested is implemented, but also closest to the piezoelectric resonator element 38 to be tested, and the wiring lines 34A and 34B are cut when the electronic parts 10 undergo the individualization.

The sheet substrate 54 is a member before the base substrates 12 of the electronic parts 10 undergo the individualization. On the sheet substrate 54, the substrate regions 56, which correspond to the respective electronic parts 10, are arranged in a matrix (9 substrate regions in the present embodiment). Dividing grooves 58 along which the sheet substrate 54 is divided are formed along the boundaries between the substrate regions 56. The dividing grooves 58 are perpendicular to each other, and it is noted for ease of description that each of the dividing grooves 58 in one direction is called a first boundary line and each of the dividing grooves 58 in the other direction is called a second boundary line, and that the substrate regions 56 are numbered (from first to ninth).

On the upper surface of the sheet substrate 54 (mounting surface 14 of base substrate 12), the mount electrodes 24A and 24B, the connection electrodes 20, the routing electrodes 22A, 22B, 22C, and 22D, and the metalized portion 28 described above are disposed in each of the substrate regions 56, as shown in FIG. 2 and other figures.

The implementation electrodes 18A, 18C, 18C, and 18D described above are disposed on the rear surface of each of the substrate regions 56 (implementation surface 16 of base substrate 12), as shown in FIG. 4 and other figures. The through electrodes 26, each of which electrically connects the corresponding implementation electrode 18 and connection electrode 20 to each other, are provided in each of the substrate regions 56.

In the arrangement described above, the implementation electrodes 18 are so disposed that they surround an intersection position 60 of the first boundary line (dividing groove 58) and the second boundary line (dividing groove 58). That is, the implementation electrode 18C in the first substrate region (eighth substrate region 56), the implementation electrode 18A in one of the second substrate regions (seventh substrate region 56), the implementation electrode 18B in the third substrate region (fifth substrate region 56), and the implementation electrode 18D in another of the second substrate regions (fourth substrate region 56) are so disposed that they surround the intersection position. Further, the mount electrodes 24A and 24B, which are connected to the piezoelectric resonator element 38, are disposed in the first substrate region (eighth substrate region 56) in positions shifted toward the intersection position 60.

The wiring line 34A is disposed in a position facing the routing electrode 22A in the first substrate region (eighth substrate region 56), and the wiring line 34A extends across the dividing groove 58 next thereto (boundary between eighth substrate region 56 and adjacent substrate region) and is connected to the implementation electrode 18A in one of the second substrate regions (seventh substrate region 56), as shown in FIGS. 2 and 4. Further, the wiring line 34A and the routing electrode 22A are electrically connected to each other via the corresponding through electrode 26.

Similarly, the wiring line 34B is disposed in a position facing the routing electrode 22B in the first substrate region (eighth substrate region 56), and the wiring line 34B extends across the dividing groove 58 next thereto (boundary between eighth substrate region 56 and adjacent substrate region) and is connected to the implementation electrode 18B (Vc) in the third substrate region (fifth substrate region 56). Further, the wiring line 34B and the routing electrode 22B are electrically connected to each other via the corresponding through electrode 26.

In the present embodiment, before the sheet substrate 54 is divided, the piezoelectric resonator element 38 disposed in the first substrate region (eighth substrate region 56) is electrically connected via the wiring line 34A to the implementation electrode 18A in one of the second substrate regions (seventh substrate region 56), which is one of the implementation electrodes 18 that surround the intersection position 60, toward which the piezoelectric resonator element 38 is shifted. Further, the piezoelectric resonator element 38 is electrically connected to the implementation electrode 18B in the third substrate region (fifth substrate region 56) via the wiring line 34B. That is, in the input/output test performed on the piezoelectric resonator element 38 in the first substrate region after all the piezoelectric resonator elements 38 are implemented on the sheet substrate 54, no test electrode needs to be newly provided, but the implementation electrodes 18 in the second substrate regions can instead be used as test electrodes. A sufficient contact area of the test electrode in each of the electronic parts 10 that is necessary for a test probe 68, which will be described later, can therefore be ensured.

On the other hand, the wiring lines 34A and 34B are cut when the sheet substrate 54 is divided along the dividing grooves 58, and each of the piezoelectric resonator elements 38 can be electrically connected only to the integrated circuit 50 disposed in the same substrate region 56. In the test, the wiring lines 34A and 34B are connected to the implementation electrode 18A in one of the second substrate regions (seventh substrate region 56) and the implementation electrode 18B in the third substrate region (fifth substrate region 56), which are closest to the mount electrodes 24A and 24B, respectively, whereby each of the wiring lines can be designed to be a short length.

The wiring lines 34A and 34B are left after the individualization of the electronic parts 10 (FIGS. 5 and 6), but the length of each of the left wiring lines 34A and 34B is very short. According to the sheet substrate 54 and the electronic parts 10, the amount of parasitic capacitance acting on the piezoelectric resonator element 38 and the integrated circuit 50 after the sheet substrate 54 is divided is therefore reduced.

Among the first to ninth substrate region 56, which form the sheet substrate 54, the wiring lines 34A and 34B present in some substrate regions 56 disposed at the circumferential edge of the sheet substrate 54, specifically, substrate regions 56 (first, second, third, fourth, and seventh), in each of which the piezoelectric resonator element 38 (drawn electrodes 46A, 46B) is disposed in a position shifted toward the circumferential edge of the sheet substrate 54, have no substrate region 56 to which the wiring lines 34A and 34B are connected, as shown in FIGS. 1 and 3. In this case, the test performed after the implementation of the piezoelectric resonator elements 38 cannot be performed only with the implementation electrodes 18.

In view of the fact described above, substrate pieces 62A and 62B extend from the substrate regions 56 described above across the dividing grooves 58 next thereto. A first substrate piece 62A and a first substrate piece 62B extend from the first substrate region 56. A second substrate piece 62B extends from the second substrate region 56. A third substrate piece 62B extends from the third substrate region 56. A second substrate piece 62A extends from the fourth substrate region 56. A third substrate piece 62A extends from the seventh substrate region 56. Further, a test electrode 64 is provided on the rear surface of each of the substrate pieces 62A and 62B. Each wiring line 34A extends from the substrate region 56 in which the wiring line 34A is disposed, extends across the dividing groove 58 next to the substrate region 56 to the substrate piece 62A, and is connected to the test electrode 64, whereas each wiring line 34B extends from the substrate region 56 in which the wiring line 34B is disposed, extends across the dividing groove 58 next to the substrate region 56 to the substrate piece 62B, and is connected to the test electrode 64.

In the configuration described above, the input/output test performed on the piezoelectric resonator element 38 in the substrate region 56 being tested may be performed, in the case of the arrangement shown in FIG. 1, simply by allowing the test probes 68 to come into contact with the implementation electrode 18A in the substrate region 56 or the test electrode 64 on the substrate piece 62A to the left of the substrate region 56 being tested and the implementation electrode 18B in the substrate region 56 or the test electrode 64 on the substrate piece 62B immediately above the substrate region 56 being tested.

In the test described above, two test probes 68 suffice. On the other hand, the implementation electrodes 18 and the test electrodes 64, which are electrically connected to the piezoelectric resonator elements 38, differ from each other on the sheet substrate 54. In view of the fact described above, the number of test probes 68 to be provided may be set to be equal to the total number of implementation electrodes 18 and test electrodes 64 used in all the tests (15 test probes in the present embodiment), and the test probes 68 may be allowed to come into contact with the electrodes at the same time for simultaneous input/output test of all the piezoelectric resonator elements present on the sheet substrate 54.

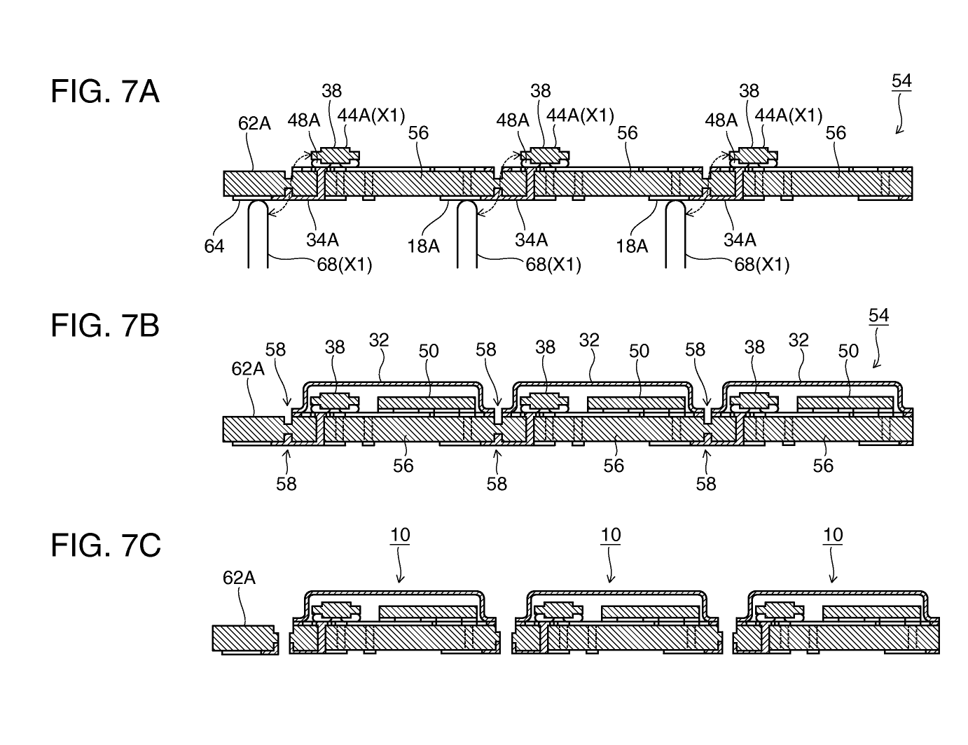

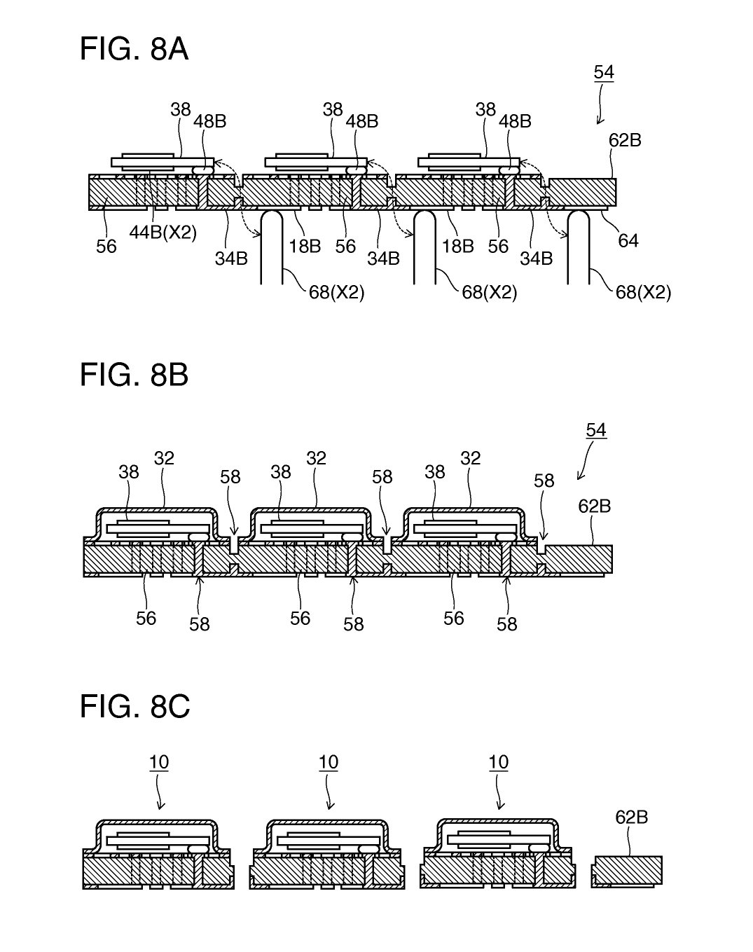

A description will next be made of steps of manufacturing the electronic parts according to the present embodiment. FIGS. 7A to 7C and 8A to 8C are cross-sectional views taken along the lines A-A and B-B in FIG. 1, respectively, and showing steps of manufacturing the electronic parts according to the present embodiment.

The sheet substrate 54 is formed and the piezoelectric resonator element 38 is implemented in each of the substrate regions 56, followed by the input/output test on each of the piezoelectric resonator elements 38 by allowing the test probes 68 to come into contact with the implementation electrodes 18A and 18B or the test electrodes 64, as shown in FIGS. 7A and 8A. When it is difficult to excite the piezoelectric resonator elements 38 under the atmospheric pressure, the piezoelectric resonator elements 38 are excited in a vacuum environment.

One of the test probes 68 (X1) is electrically connected to the excitation electrode 44A (X1) of the piezoelectric resonator element 38 being tested via the wiring line 34A by allowing the test probe 68 (X1) to come into contact with the implementation electrode 18A or the relevant test electrode 64, as shown in FIG. 7A. Similarly, the other test probe 68 (X2) is electrically connected to the excitation electrode 44B (X2) of the piezoelectric resonator element 38 being tested via the wiring line 34B by allowing the test probe 68 (X2) to come into contact with the implementation electrode 18B or the relevant test electrode 64, as shown in FIG. 8A. FIG. 7A shows that the one test probe 68 and the excitation electrode 44A, which are connected to each other with the broken line, are electrically connected to each other, and FIG. 8A shows that the other test probe 68 and the excitation electrode 44B, which are connected to each other with the broken line, are electrically connected to each other.

The input/output test on each of the piezoelectric resonator elements 38 by using the test probes 68 allows identification of a nonoperational piezoelectric resonator element 38 or a piezoelectric resonator element 38 that is operational but its resonant frequency or CI value does not fall within an acceptable range.

In a manufacturing step according to the present embodiment, identification test information formed of information on the positions of the test probes 68 accompanied by whether or not the corresponding piezoelectric resonator element 38 has passed the test is generated. A collet (not shown) to which each integrated circuit 50 is attached is then operated based on the identification test information and will implement no integrated circuit 50 based on the identification test information in the substrate region 56 where a piezoelectric resonator element 38 that has not passed the test is implemented. The integrated circuit 50 is implemented only in the substrate region 56 where an implemented piezoelectric resonator element 38 operates in a satisfactory manner. In this way, no integrated circuit 50 is wasted and cost reduction is achieved.

After the integrated circuit 50 is implemented in each of the substrate regions 56, the cap 32 is implemented in each of the substrate regions 56, as shown in FIGS. 7B and 8B. The electronic parts 10 are separated into individual parts by pressing a blade (not shown) along the dividing grooves 58 of the sheet substrate 54, as shown in FIGS. 7C and 8C. In the individualization, the wiring lines 34A and 34B are cut into two located on opposite sides of each of the dividing grooves 58 and left in the electronic parts 10 (FIGS. 5 and 6).

In the manufacturing steps described above, since the piezoelectric resonator element 38 being tested is connected to the implementation electrodes 18 that are not only present in second substrate region and third substrate region but also closest to the piezoelectric resonator element 38 being tested, the wiring lines 34A and 34B that connect the piezoelectric resonator element 38 and the implementation electrodes 18 can be short. The wiring lines 34A and 34B left in each of the substrate regions 56 (base substrate 12) after the sheet substrate 54 is divided can therefore be short. The method for manufacturing the electronic parts 10 described above therefore not only ensures sufficient contact areas of the test electrodes in each of the electronic parts 10 that are necessary for the test probes 68 but also reduces the amount of parasitic capacitance acting on the piezoelectric resonator element 38 and the integrated circuit 50.

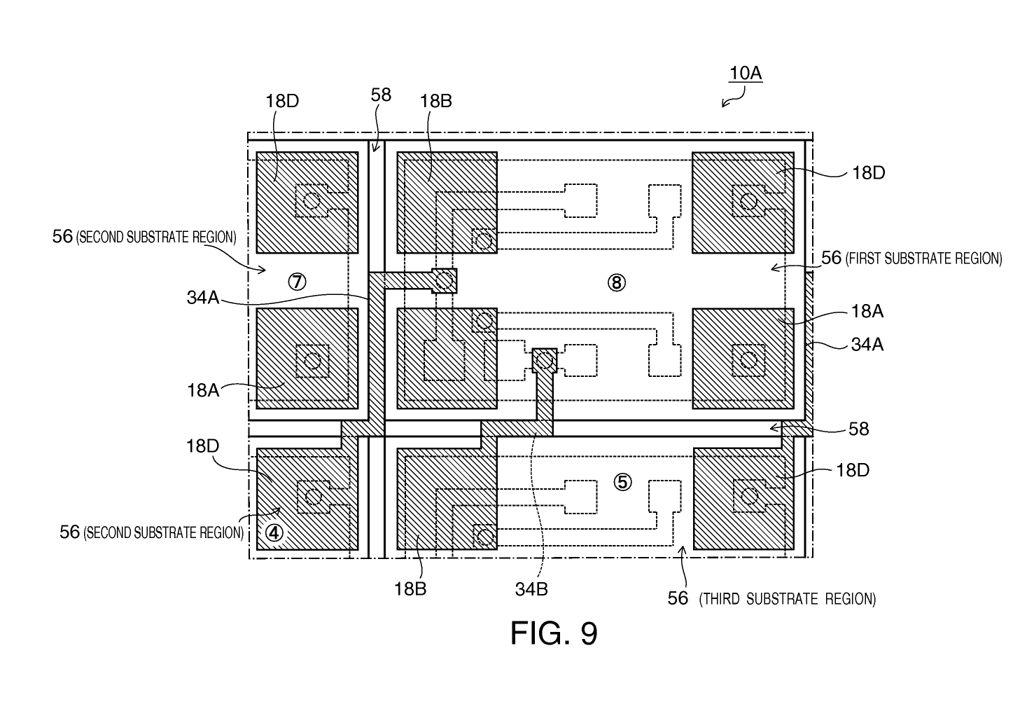

FIG. 9 is a partial bottom view of electronic parts (before individualization) according to a variation. The basic configuration of electronic parts 10A (including sheet substrate 54) according to the variation is the same as that in the embodiment described above but differs therefrom in terms of the positions of the implementation electrodes 18, the positions of the wiring lines 34A and 34B, and the connection destinations thereof. That is, each of the wiring lines 34A and 34B has a portion extending along the corresponding dividing groove 58, and the implementation electrodes 18 in each of the substrate regions 56 are disposed in positions slightly inward from the circumferential edge of the substrate region 56. This configuration prevents the wiring lines 34A and 34B from forming short circuits with implementation electrodes other than the implementation electrodes 18 to which the wiring lines 34A and 34B are connected. The wiring lines 34A and 34B can therefore reach the contour of the first substrate region by following the shortest route to the dividing groove 58 in the first substrate region. Further, the portion of each of the wiring lines 34A and 34B that extends along the dividing groove 58 is separated from the electronic part 10 after the individualization of the electronic parts 10. The configuration described above can therefore further shorten the remaining length of each of the wiring lines 34A and 34B in the electronic part 10, whereby the amount of parasitic capacitance acting on the piezoelectric resonator element 38 and the integrated circuit 50 can be further reduced.

Further, in the present variation, the wiring line 34A disposed in the first substrate region (eighth substrate region 56) can alternatively be connected to the implementation electrode 18D (GND) in one of the second substrate regions (fourth substrate region 56), as shown in FIG. 9. Similarly, the wiring line 34B disposed in the first substrate region (eighth substrate region 56) can alternatively be connected to the implementation electrode 18B (GND) in the third substrate region (fifth substrate region 56).

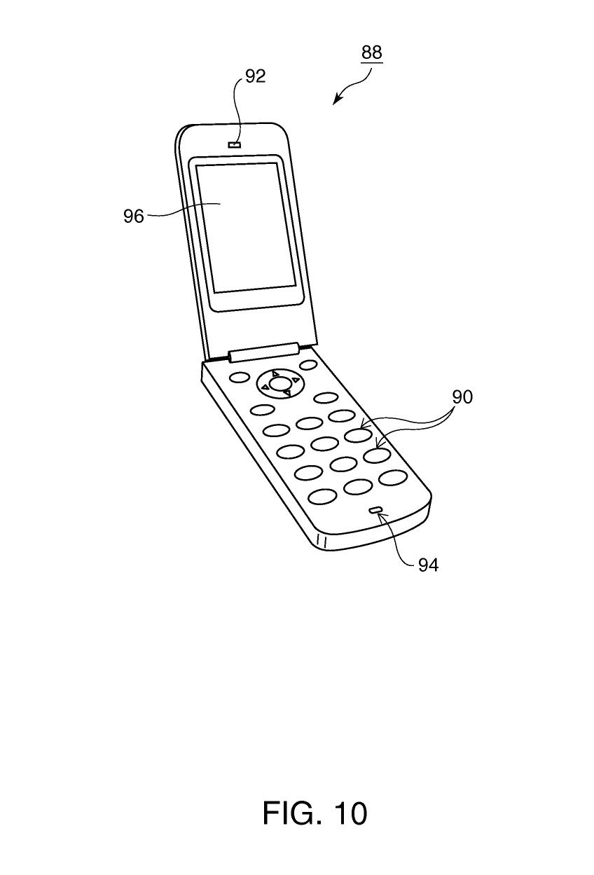

FIG. 10 is a schematic view showing an electronic apparatus (mobile terminal) that accommodates the electronic part according to the present embodiment. In FIG. 10, a mobile terminal 88 (including PHS) includes a plurality of operation buttons 90, a receiver 92, and a transmitter 94, and a display 96 is disposed in the region between the operation buttons 90 and the receiver 92. A recent mobile terminal 88 of this type also has a GPS capability. To this end, the mobile terminal 88 accommodates the electronic part 10 (piezoelectric device) according to the present embodiment as a clock source in a GPS circuit.

An electronic apparatus that accommodates the electronic part 10 according to the present embodiment is not limited to the mobile terminal 88 described above and can be used with an advanced mobile phone, a digital still camera, a personal computer, a laptop personal computer, a television receiver, a video camcorder, a video tape recorder, a car navigation system, a pager, an inkjet-type liquid ejection apparatus, an electronic notebook, a desktop calculator, an electronic game console, a word processor, a workstation, a TV phone, a security television monitor, electronic binoculars, a POS terminal, a medical apparatus (such as electronic thermometer, blood pressure gauge, blood sugar meter, electrocardiograph, ultrasonic diagnostic apparatus, and electronic endoscope), a fish finder, a variety of measuring apparatus, a variety of instruments (such as instruments in vehicles, air planes, and ships), and a flight simulator.

The entire disclosure of Japanese Patent Application No. 2012-112201, filed May 16, 2012 is expressly incorporated by reference herein.

What is claimed is:

1. A method for manufacturing an electronic part, the method comprising:
a first step of
providing a sheet substrate having a first substrate region, a second substrate region, and a third substrate region and including a pair of first electronic device mounting pads disposed on amounting surface of the first substrate region and implementation electrodes disposed on the side facing away from amounting surface of each of the second and third substrate regions, and
disposing a first wiring line that electrically connects one terminal of the first electronic device mounting pads to one of the implementation electrodes disposed in the second substrate region, the implementation electrode disposed in the second substrate region in the vicinity of the first electronic device mounting pads, and a second wiring line that electrically connects the other terminal of the first electronic device mounting pads to one of the implementation electrodes disposed in the third substrate region, the implementation electrode disposed in the third substrate region in the vicinity of the first electronic device mounting pads;
a second step of
disposing a first electronic device on the first electronic device mounting pads and
inputting and outputting a signal to and from the first electronic device via the implementation electrode disposed in the second substrate region and connected to the first wiring line and the implementation electrode disposed in the third substrate region and connected to the second wiring line; and
a third step of dividing the sheet substrate along the first substrate region, the second substrate region, and the third substrate region to cut the first and second wiring lines.

2. The method for manufacturing an electronic part according to claim 1,
wherein a second electronic device mounting pad electrically connected to the first electronic device mounting pads is further provided on the mounting surface of the first substrate region, and
after the second step, a second electronic device is disposed on the second electronic device mounting pad in the first substrate region.

3. A method for testing an electronic part, the method comprising:
providing a sheet substrate having a first substrate region, a second substrate region, and a third substrate region, having a first electronic device disposed on a pair of first electronic device mounting pads on a mounting surface of the first substrate region, and having implementation electrodes disposed on the side facing away from a mounting surface of each of the second and third substrate regions;
disposing a first wiring line that electrically connects one terminal of the first electronic device mounting pads to one of the implementation electrodes disposed in the second substrate region, the implementation electrode disposed in the second substrate region in the vicinity of the first electronic device mounting pads, and a second wiring line that electrically connects the other terminal of the first electronic device mounting pads to one of the implementation electrodes disposed in the third substrate region, the implementation electrode disposed in the third substrate region in the vicinity of the first electronic device mounting pads; and
disposing a first electronic device on the first electronic device mounting pads and inputting and outputting a signal to and from the first electronic device via the implementation electrode disposed in the second substrate region and connected to the first wiring line and the implementation electrode disposed in the third substrate region and connected to the second wiring line.

4. A sheet substrate comprising:
a first substrate region, a second substrate region, and a third substrate region;
a pair of first electronic device mounting pads disposed on a mounting surface of the first substrate region;
implementation electrodes disposed on the side facing away from a mounting surface of each of the second and third substrate regions;
a first wiring line that electrically connects one terminal of the first electronic device mounting pads to one of the implementation electrodes disposed in the second substrate region, the implementation electrode disposed in the second substrate region in the vicinity of the first electronic device mounting pads; and
a second wiring line that electrically connects the other terminal of the first electronic device mounting pads to one of the implementation electrodes disposed in the third substrate region, the implementation electrode disposed in the third substrate region in the vicinity of the first electronic device mounting pads.

5. The sheet substrate according to claim 4,
wherein the first substrate region is disposed next to a circumferential edge of the sheet substrate,
in a region where a region close to the first electronic device mounting pads is located next to the circumferential edge of the sheet substrate, a substrate piece is provided in the vicinity of the first substrate region, and
a first test electrode connected to the first wiring line and a second test electrode connected to the second wiring line are provided on the rear side of the substrate piece.

6. An electronic part comprising:
a second electronic device mounting pad disposed on the sheet substrate according to claim 4 and electrically connected to the first electronic device mounting pads;
a first electronic device disposed on the first electronic device mounting pads; and
a second electronic device disposed on the second electronic device mounting pad,
wherein the sheet substrate is divided along the first substrate region, the second substrate region, and the third substrate region into individual pieces.

7. An electronic part comprising:
a second electronic device mounting pad disposed on the sheet substrate according to claim 5 and electrically connected to the first electronic device mounting pads;
a first electronic device disposed on the first electronic device mounting pads; and
a second electronic device disposed on the second electronic device mounting pad,
wherein the sheet substrate is divided along the first substrate region, the second substrate region, and the third substrate region into individual pieces.

8. The electronic part according to claim 6,
wherein the first electronic device is an resonator element, and
the second electronic device is an integrated circuit.

9. The electronic part according to claim 7,
wherein the first electronic device is an resonator element, and
the second electronic device is an integrated circuit.

10. An electronic apparatus in which the electronic part according to claim 6 is disposed.

11. An electronic apparatus in which the electronic part according to claim 7 is disposed.

12. An electronic apparatus in which the electronic part according to claim 8 is disposed.

13. An electronic apparatus in which the electronic part according to claim 9 is disposed.
